(19) United States
(12) Patent Application Publication
(10) Pub. No.: US 2025/0211072 A1
(43) Pub. Date: Jun. 26, 2025

(54) FLEX PCB IMPLEMENTATION FOR HALL EFFECT SENSOR IN BLDC MOTOR

(71) Applicant: SL Monevideo Technology, Inc., Pleasant Prairie, WI (US)

(72) Inventors: Dustin D. Elliott, Grayslake, IL (US); Lonnie James Flickinger, Montevideo, MN (US)

(21) Appl. No.: 18/989,999

(22) Filed: Dec. 20, 2024

Related U.S. Application Data
(60) Provisional application No. 63/612,730, filed on Dec. 20, 2023.

(51) Int. Cl. H02K 11/33; H05K 1/14; H05K 1/18

(52) U.S. Cl. CPC H02K 11/33; H05K 1/147; H05K 1/181; H05K 1/189; H02K 2211/03; H05K 2201/10151

(57) ABSTRACT

Combinations of flexible and rigid PCBs are disclosed to support Hall-effect sensors in BLDC motors with improved positional accuracy and reduced manual operations. Use of one or more flexible PCB portions or segments allow the support and electrical connections for an array of Hall-effect sensors to be manufactured in a planar configuration using automated pick and place equipment. The flexible portions or segments of the PCB include conductive traces to transmit power to and receive a signal from the Hall-effect sensors. Pads to which the leads of a surface mount Hall-effect sensor will be mounted are formed on the flex PCB or on a rigid PCB segment connected to a flex PCB segment. Flexible PCB material allows the PCB assembly to transition from a planar configuration to one where the Hall-effect sensors are not in a common plane.

### FIELD OF THE INVENTION

The present invention relates to brushless DC motors and more particularly to the positioning of Hall-effect sensors to sense magnetic fields created by a permanent magnet rotor of the motor.

### BACKGROUND OF THE INVENTION

Brushless DC (BLDC) motors use electronic instead of mechanical commutation to control power distribution in the motor. Hall-effect sensors mounted in the motor are used to detect the position of the rotor of the motor, and this position information is used by the electronic motor controller to accurately determine the correct time and sequence to apply current to the coils of the stator to rotate the rotor. To produce the maximum amount of torque on the motor shaft in a BLDC motor, the timing between the current flowing through the stator coils and the rotational position of the rotor and shaft must be as accurate as possible. Inaccuracies in applying current to the stator coils relative to the position of the rotor magnets reduces the torque generated by the motor and reduces the overall efficiency of the motor.

FIG. 1 schematically illustrates a prior art BLDC motor 2 using Hall-effect sensors 3 to provide signals to a motor control circuit 4. The BLDC motor 2 of FIG. 1 is a multi-pole motor with a three-phase winding 5 that employs three Hall-effect sensors 3 to detect the position of the rotor 6. The angular spacing of the Hall-effect sensors is dependent upon the configuration of the BLDC motor 2. The Hall-effect sensors 3 are positioned within the motor 2 in close proximity to permanent magnets 7 on the rotor 6 to detect the magnetic field of the rotor magnets 7 and thereby the rotational position of the rotor 6. The Hall-effect sensors 3 illustrated in FIGS. 1 and 2 are through hole components with three conductive legs that are inserted through holes in a printed circuit (PC) board and soldered in place. As shown in FIG. 2, the through hole Hall-effect sensors 3 project perpendicular to a plane transverse to the rotational axis of the motor 2 and are positioned in an axial position overlapping with one end of the permanent magnets 7 on the rotor 6. Those skilled in the art understand that the permanent magnets 7 are positioned so that a magnetic field of alternating north-south polarity extends radially from the rotor 6. As the magnets 7 move past each sensor, the Hall-effect sensors 3 produce an electronic signal that is delivered to the motor control circuit 4 and used to electronically commutate the BLDC motor 2. The BLDC motor 2 of FIG. 2 illustrates a rotor 8 with 12 permanent magnets 7. The number of permanent magnets and number of coils in the motor stator are selected to meet desired criteria for motor performance according to principles known to those skilled in the art.

Using through hole Hall-effect sensors requires that each sensor be hand soldered to a PC board oriented perpendicular to a longitudinal axis of the motor. Positioning of the sensors relative to the PC board, the stator, and the rotor typically requires adjustment by hand to ensure the sensors are in a position relative to the rotor magnets to consistently and accurately detect the position of the rotor. The angular spacing of the through hole components around a rotational axis of the motor may also be affected by manual placement and adjustment. It is also necessary to adjust the array of Hall-effect sensor relative to the poles of the stator so the signals produced by the Hall-effect sensors are synchronized with magnetic fields generated when electrical current is applied to the stator coils.

BLDC motors may incorporate a ferrite core or may be constructed without a ferrite core in a so-called “coreless” motor configuration. Hall-effect sensors in a BLDC motor are used to detect rotor position in conjunction with coreless brushless DC motors and BLDC motors with a core. Coreless BLDC motors are electronically commutated using Hall-effect sensors and the principles of using Hall-effect sensors in a BLDC motor discussed with respect to disclosed embodiments can be applied to coreless brushless DC motors. Further, BLDC motors are commonly configured with a stator surrounding a rotor in an “inrunner” configuration and with a rotor surrounding a stator in an “outrunner” configuration. Those skilled in the art will recognize that the operational characteristics of inrunner and outrunner BLDC motor configurations are similar and concepts applicable to inrunner BLDC motors are also applicable to outrunner BLDC motors.

There is a need for a BLDC motor and methods of manufacture that reduce the number of manual operations needed to install and calibrate Hall-effect sensors used for sensing rotor position.

There is a need for a BLDC motor and methods of manufacture that increase the accuracy of Hall-effect sensor position within the motor.

There is a need to support Hall-effect sensors in a BLDC motor in a manner that allows for a compact and efficient BLDC motor configuration.

### SUMMARY OF THE INVENTION

Combinations of flexible and rigid PCBs are disclosed to support Hall-effect sensors in BLDC motors with improved positional accuracy and reduced manual operations. Use of one or more flexible PCB portions or segments allow the support and electrical connections for an array of Hall-effect sensors to be manufactured in a planar configuration using automated pick and place equipment. Automated placement of the Hall-effect sensors on the PCB reduces manual operations and improves the positional accuracy of the sensors on the PCB. The flexible portions or segments of the PCB include conductive traces to transmit power to and receive a signal from the Hall-effect sensors. The same two power connections can be used to supply power and ground to the three Hall-effect sensors using conductive traces on the PCB. Separate conductive traces to each Hall-effect sensor provide a path for signals from the Hall-effect sensors that will be used by a motor controller to commutate the BLDC motor. Pads to which the leads of a surface mount Hall-effect sensor will be mounted are formed on the flex PCB or on a rigid PCB segment connected to a flex PCB segment. In the disclosed embodiments, the electrical leads of a surface mount Hall-effect sensor are soldered to the pads of the PCB using a reflow soldering process, although other connection methods such as crimping are possible. The electrical connections to the Hall-effect sensors may be located on a flexible portion of the PCB or on a rigid portion of the PCB. Once the PCB assembly is completed with soldered connections and wires or connectors for power and signals, the PCB assembly is ready to be installed in the BLDC motor.

According to aspects of the disclosure, the flexible portions or segments of the PCB are arranged so that the flex or rigid PCB segments to which the Hall-effect sensors are attached can be moved from a position in a plane with the other portions of the PCB assembly to a position adjacent the permanent magnets on the rotor. In some disclosed embodiments, at least a portion of the PCB assembly is perpendicular to the orientation of the portions or segments of the PCB assembly supporting the Hall-effect sensors when the PCB assembly is installed in a BLDC motor. The disclosed invention is not limited to a configuration where portions of the PCB assembly are perpendicular to each other, and including strategically placed flexible PCB segments allow for a range of relative positions between the Hall-effect sensors and the other parts of the PCB assembly.

The disclosed embodiments include a PCB constructed entirely of flexible PCB material. In this embodiment, the flexible PC board includes a flexible PC board defining a plurality of component locations and conductors extending from the component locations to an interconnect portion of the flexible PC board. A surface mount Hall-effect sensor is secured to the flexible PC board at each of the component locations, with electrical leads of the surface mount Hall-effect sensors connected to the conductors. The flexible PC board is secured in a BLDC motor in a fixed position relative to the stator and the rotor, with the Hall-effect sensors positioned to detect the magnetic flux of the magnets so that the Hall-effect sensors change state as each of the magnets passes each of the Hall-effect sensors. Signals from each of the Hall-effect sensors pass through a conductive trace of the flexible PCB to the interconnect portion, where they are connected to wires for delivery to a motor control circuit to electronically commutate the BLDC motor.

Alternate embodiments include flexible PCB segments or portions and rigid PCB segments or portions. The flexible PCB segments or portions are arranged to span areas of the PCB assembly where relative movement between PCB segments will be required to position the Hall-effect sensors to detect the position of the rotor. Rigid PCB portions may be used for the interconnect portion of the PCB assembly, where wires are connected to the PCB assembly. Rigid PCB portions may be used to support each of the Hall-effect sensors and a flex PCB portion is used to connect the rigid PCB portion to the rest of the PCB. A rigid PCB may be used to define both the interconnect portion and a body of the PCB assembly, while flexible PCB segments include the component locations where Hall-effect sensors are mounted. Flexible PCB segments allow the Hall-effect sensors to be positioned in a range of angular positions relative to the remainder of the PCB assembly. Any of the disclosed PCB assemblies may include a projection received in a pocket or receptacle to define a specific orientation of the Hall-effect sensors relative to the stator of a BLDC motor. The flexible PC board allows the use of surface mount Hall-effect sensors instead of through hole components. The flexible PC board can be populated using automated pick and place equipment to reduce labor costs and increase the accuracy of sensor positions on the PCB assembly and within the BLDC motor. The disclosed flexible or combination of flex and rigid PCB can be populated with components and provided with connection wires to form a PCB assembly that can be incorporated into a brushless DC motor with minimal further manual operations. The disclosed PCB assembly may be used in cored and coreless brushless DC motors and can be adapted to a wide variety of brushless DC motor configurations with minimal change to the other components of the brushless DC motor. Further, the disclosed PCB assemblies can be configured for use in BLDC motors where a rotor surrounds the stator, although the disclosed embodiments are BLDC motors with a rotor surrounded by a stator.

### BRIEF DESCRIPTION OF THE DRAWINGS

FIGS. 1 and 2 illustrate prior art BLDC motors using through hole Hall-effect sensors;

FIG. 3 illustrates a first embodiment of a PCB assembly with three surface mount Hall-effect sensors according to aspects of the disclosure;

FIG. 4 illustrates the PCB assembly of FIG. 3 mounted to a BLDC motor stator according to aspects of the disclosure;

FIG. 5 is a top plan view of the PCB assembly of FIG. 3 secured to a positioning ring according to aspects of the disclosure;

FIG. 6 is a longitudinal cross-section of a BLDC motor incorporating the PCB assembly and positioning ring of FIG. 5 according to aspects of the disclosure;

FIG. 7 is a cross section of a BLDC motor taken perpendicular to the rotor axis of rotation incorporating the PCB assembly and positioning ring of FIG. 5 according to aspects of the disclosure;

FIG. 8 is a top plan view of a second embodiment of a PCB assembly according to aspects of the disclosure;

FIG. 9 is a top perspective view of the PCB assembly of FIG. 8 secured to a positioning ring according to aspects of the disclosure;

FIG. 10 is a top plan view of a third embodiment of a PCB assembly according to aspects of the disclosure;

FIG. 11 is a top plan view of the PCB assembly of FIG. 10 mounted to a positioning ring according to aspects of the disclosure;

FIG. 12 is a top plan view of a fourth embodiment of a PCB assembly according to aspects of the disclosure;

FIG. 13 is a top perspective view of the PCB assembly of FIG. 12 mounted to a positioning ring according to aspects of the disclosure;

FIG. 14 is a perspective view of a motor end cap incorporating a fifth embodiment of a PCB assembly according to aspects of the disclosure;

FIG. 15 is a cross section through a BLDC motor incorporating the motor end cap and PCB assembly of FIG. 14;

FIG. 16 is a partial longitudinal cross section through a BLDC motor incorporating the motor end cap and PCB assembly of FIG. 14; and

FIG. 17 is a partial perspective view of a BLDC stator and sixth embodiment of a PCB assembly according to aspects of the disclosure.

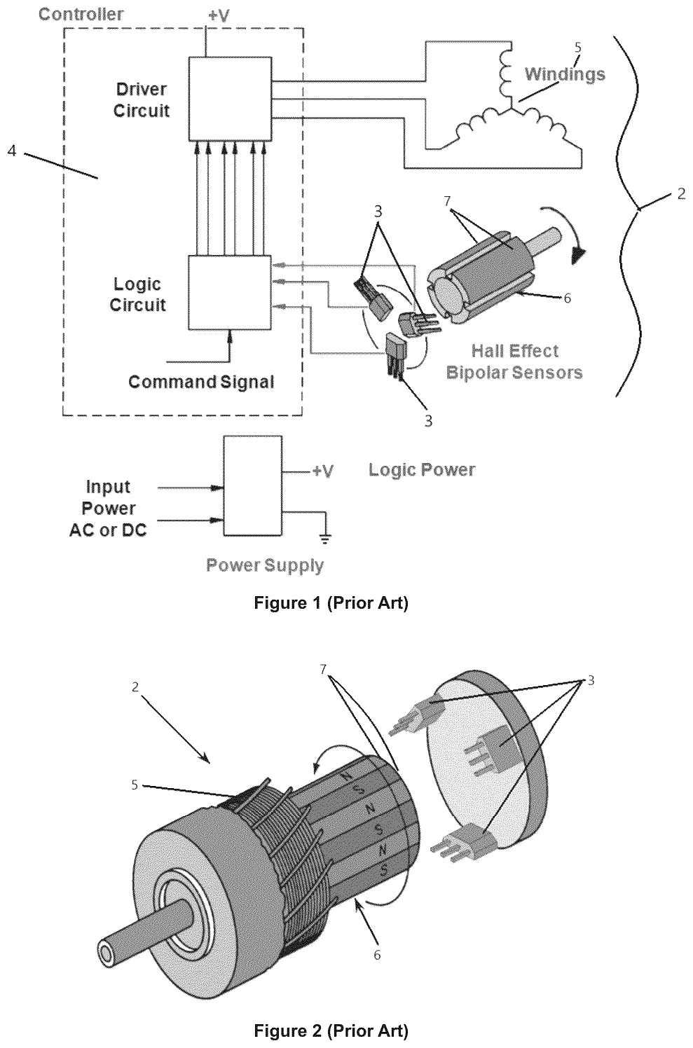

### DETAILED DESCRIPTION

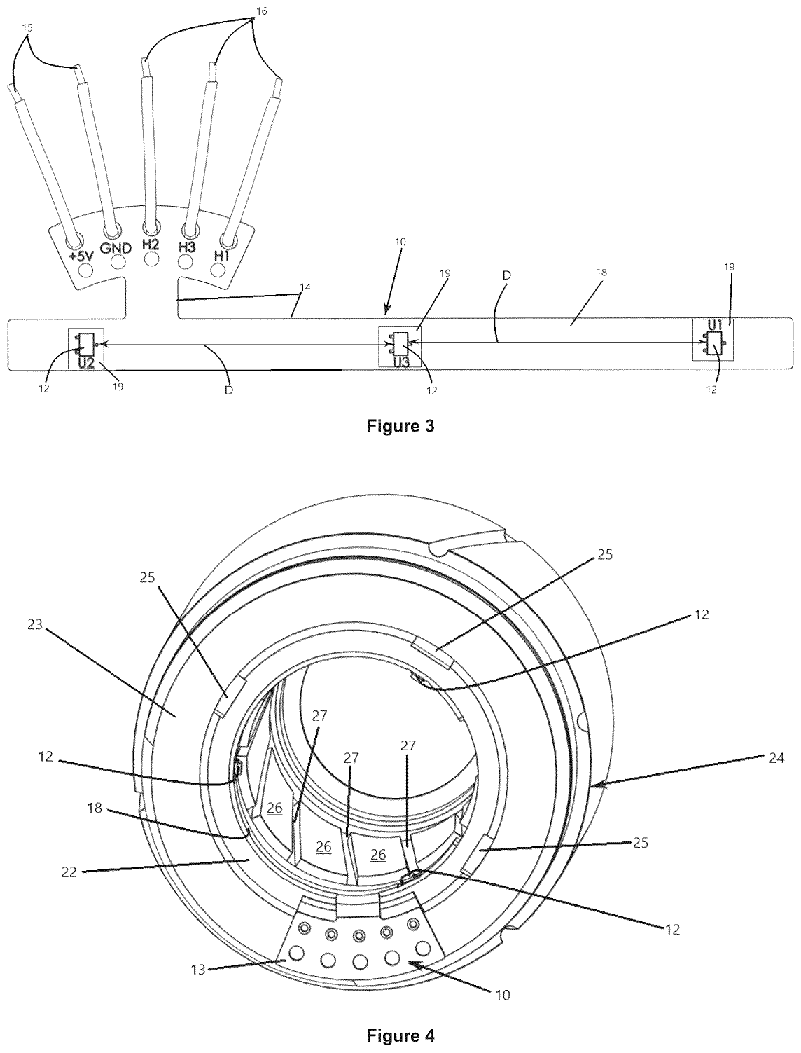

Representative examples of PCB assemblies supporting arrays of surface mount Hall-effect sensors according to aspects of the disclosure will be described with reference to FIGS. 3-17, wherein the same reference numerals represent the same or similar structures throughout the figures. FIG. 3 illustrates a first embodiment of a PCB assembly 10 that supports a plurality of surface mount Hall-effect sensors 12 for use as rotor position sensors in a BLDC motor. The PCB assembly 10 is constructed entirely of flexible PCB 14 (also referred to as “flex PCB”) and is shown in a flat state with connection wires 15, 16 and Hall-effect sensors 12 connected to the flexible PCB 14. Before installing the connection wires 15, 16, the flat flexible PCB 14 may be populated with surface mount Hall-effect sensors 12 using pick and place equipment as is known in the art. Pick and place equipment will consistently position each Hall-effect sensor 12 on the flexible PCB 14 with a degree of accuracy that is not possible when compared to manual installation and soldering of through hole Hall-effect sensors. Connection wires 15 deliver power and ground to conductive traces in the flexible PCB 14 that connect with conductive pads at component locations 19 where the Hall-effect sensors 12 are mounted to the flexible PCB 14. Signal wires 16 carry the signal of each Hall-effect sensor 12 to a motor control circuit such as controller 4 illustrated in FIG. 1. An interconnect portion 13 of the flexible PCB 14 defines openings to secure connection wires 15 and signal wires 16 to the PCB assembly 10 electrically connected to conductive traces in the flexible PCB 14. The material, thickness, bend radius, and dimensions of the flexible PCB 14 are selected to be compatible with the configuration of a BLDC motor in which the PCB assembly 10 will be used. An elongated strip 18 of the flexible PC board 14 is configured to include component locations 19 for three surface mount Hall-effect sensors 12 at a pre-determined distance D from each other along the length of the strip 18 of flexible PCB 14. The distance D between the Hall-effect sensors 12 on the flexible PCB 14 in a flat state is selected to translate into a pre-determined angular distance between the Hall-effect sensors 12 when the flexible PC board 14 is bent to conform to the inside or outside diameter of a circular support surface in a BLDC motor.

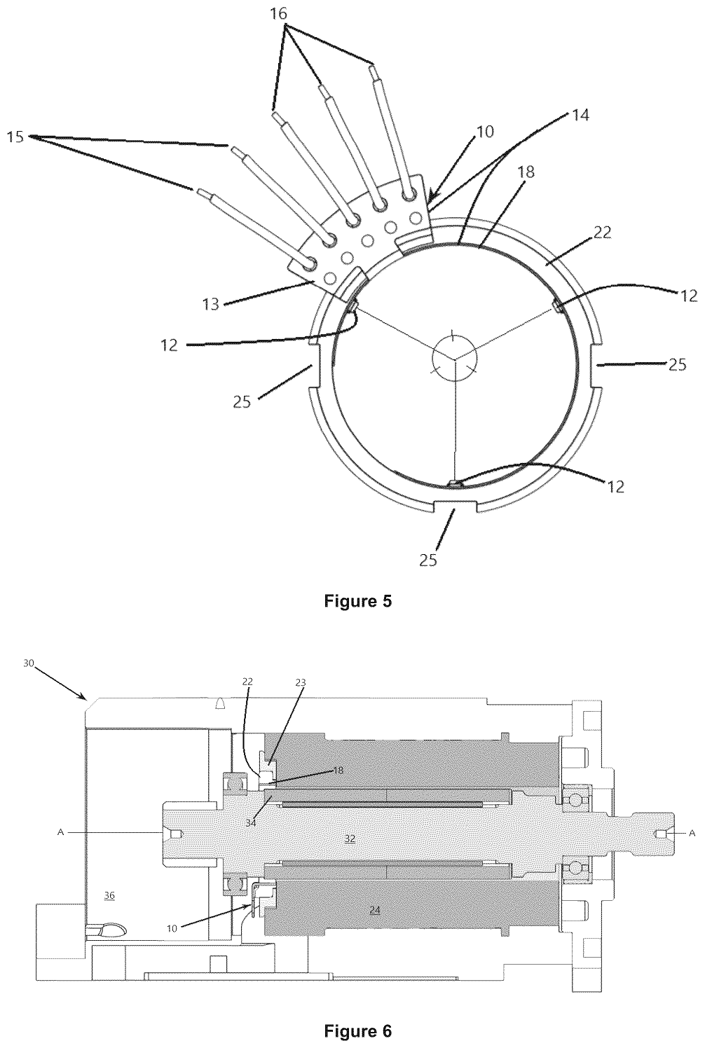

FIG. 4 illustrates the first embodiment of a PCB assembly 10 with three surface mount Hall-effect sensors 12 installed on the inside diameter of a positioning ring 22 secured to one end of a BLDC stator 24. The other components of the BLDC motor, including the rotor are removed for clarity. In this embodiment, the positioning ring 22 is received in a ring mount plug 23 and is rotatable relative to the ring mount plug 23, which allows adjustment of the rotational position of the Hall-effect sensors 12 relative to the BLDC stator 24. Connection wires 15 and signal wires 16 deliver power to and signals from the Hall-effect sensors 12 are installed so the completed PC board assembly 10 can be glued or otherwise secured into position on the positioning ring 22 without further manual operations. The flexible PCB 14 allows the strip 18 to bend and conform to the shape of the inside surface of the positioning ring 22. The flexible PCB 14 also allows the interconnect portion 13 to be bent outwardly, to a position shown in FIG. 4. The positioning ring 22 defines three notches 25 configured to receive a tool to rotate the positioning ring while it is received in the ring mount plug 23. This allows the PC board assembly 10 to be secured in a predetermined position relative to the poles 26 and coils 27 of the stator 24.

FIG. 5 illustrates the PCB assembly 10 secured to the positioning ring 22 and ready for installation into a BLDC motor according to aspects of the disclosure. The flexible PCB 14 allows the strip 18 of flexible PCB 14 supporting the Hall-effect sensors 12 to conform to the inside surface of the positioning ring 22, while the interconnect portion 13 is bent laterally outward. Both the strip 18 and interconnect portion 13 may be secured to the positioning ring 22 using a jig or fixture and adhesive or double-sided tape to ensure accurate placement. Alternatively, mechanical fasteners may be used to secure the PCB assembly 10 to the positioning ring 22. According to aspects of the disclosure, the position of the hall-effect sensors 12 relative to each other and to the longitudinal edges of the strip 18 of flexible PCB 14 are pre-determined by assembly of the surface mount Hall-effect sensors 12 to the PCB assembly 10. Securing the strip 18 of flexible PCB 14 to an inside surface of the positioning ring 22 ensures the Hall-effect sensors 12 are perpendicular to an axis of the positioning ring 22. In the BLDC motor of FIGS. 4, 6, and 7 a longitudinal edge of the strip 18 of flexible PC board 14 is perpendicular to a rotational axis A-A of the rotor 32. The surface mount Hall-effect sensors 12 are mounted to the strip 18 of flexible PCB 14 perpendicular to the longitudinal edge 28, so the orientation of the Hall-effect sensors 16 relative to the rotor magnets are consistently perpendicular to the magnetic flux projected radially from the rotor magnets 34.

FIG. 6 is a longitudinal cross section through a BLDC motor 30 incorporating the PCB assembly 10, positioning ring 22, ring mount plug 23, and stator 24 of FIGS. 3-5. FIG. 6 illustrates one end of the rotor 32 extending axially relative to the stator 24 and radially inward of the PCB assembly 10 supporting the Hall-effect sensors 12 secured to the strip 18 of flexible PCB 14. The Hall-effect sensors 12 are positioned radially outward of and very close to the magnets 34. Connection wires 15, and signal wires 16 from the PCB assembly 10 and wires from the stator coils 27 can be fed through an opening in the end of a motor housing 36 to a motor control circuit (not shown). FIG. 5 shows the Hall-effect sensors 12 are separated by equal angles of approximately 120°. The angles between Hall-effect sensors used for electronic commutation of BLDC motors are typically equal, but are not limited to angles of 120°. It will be apparent to those skilled in the art that the disclosed use of PCB assembly 10 incorporating flexible PCB 14 may allow manufacture of a BLDC motor with an improved, more compact form factor relative to prior art use of individually placed Hall-effect sensors or Hall-effect sensors mounted to a rigid PC board perpendicular to a longitudinal axis of the BLDC motor.

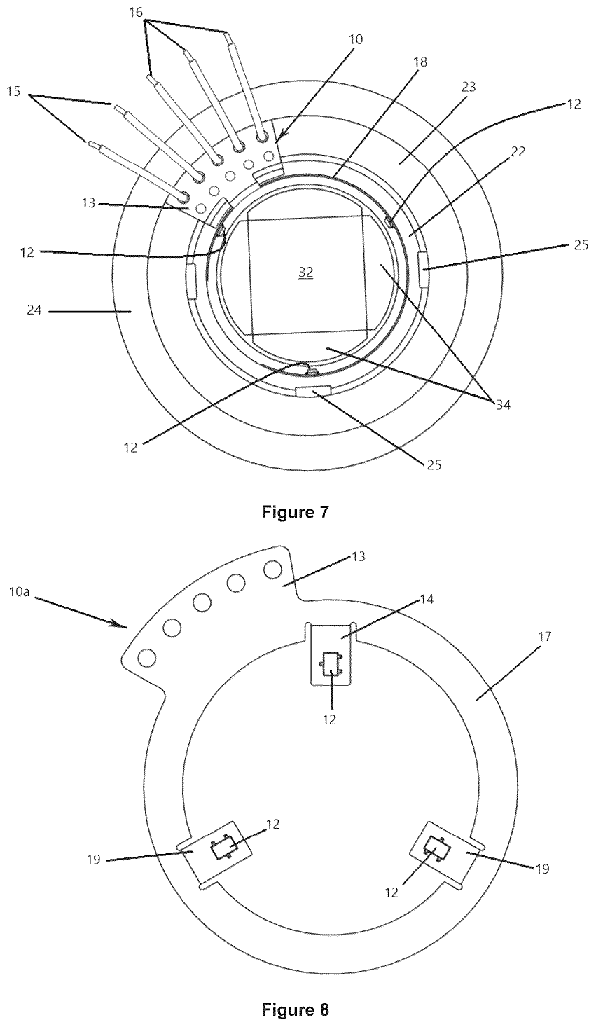

FIG. 7 is a cross section through the BLDC motor of FIG. 6, showing the stator 24, rotor 32, ring mount plug 23, positioning ring 22 and PCB assembly 10 in an assembled state. In this BLDC motor, four permanent magnets 34 of alternating polarity are secured to an outside surface of the rotor 32. The positioning ring 22 supports the Hall-effect sensors 12 in a position to detect the magnetic field projected radially from each permanent magnet 34 as it passes the Hall-effect sensors 12. Signal wires 16 carry the signals generated by the Hall-effect sensors 12 to a motor control circuit such as that illustrated in FIG. 1. During assembly, the BLDC motor is connected to test equipment and the positioning ring 22 is rotated using a tool inserted into notches 25 to adjust the position of the Hall-effect sensors 12 relative to the stator 24 to optimize performance of the motor. The positioning ring 22 is then bonded or otherwise secured to the stator 24.

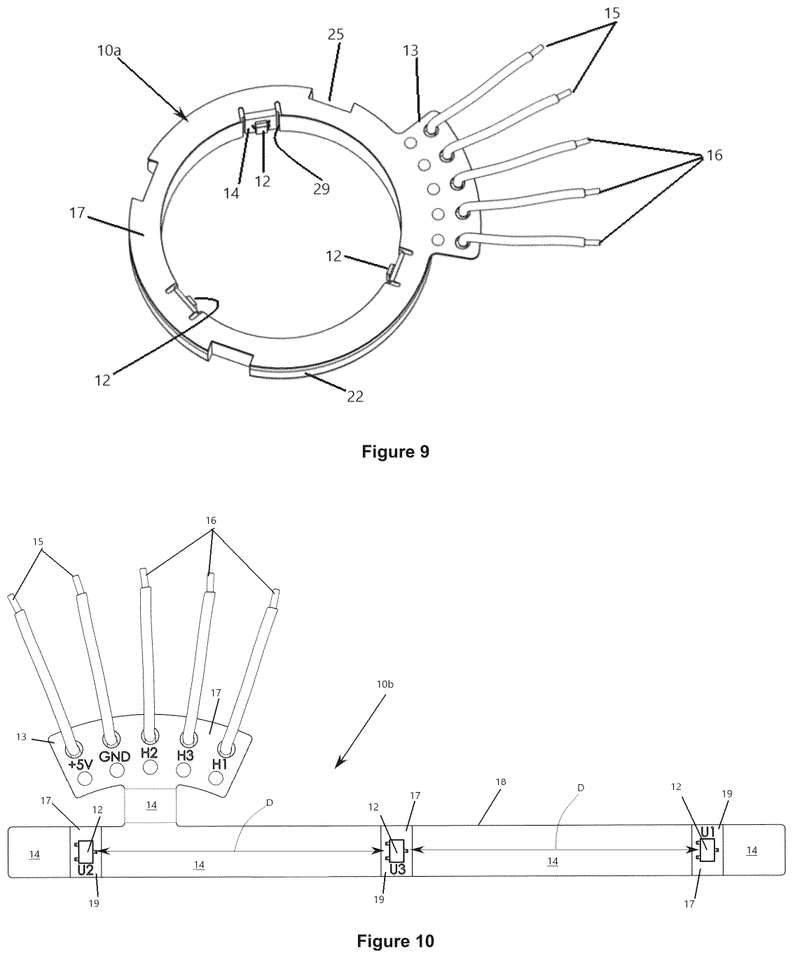

FIGS. 8 and 9 illustrate a second embodiment of a PCB assembly 10a according to aspects of the disclosure. In this embodiment, the PCB is a combination of flexible PCB 14 and rigid PCB 17. The interconnect portion 13 and a ring-shaped body of the PCB are constructed of rigid PCB 17. Component locations 19 for each of the three Hall-effect sensors 12 are constructed of flexible PCB 14. FIG. 9 illustrates the PCB assembly 10a mounted to a positioning ring 22. The positioning ring 22 defines pockets 29 to receive the component locations 19 of flexible PCB 14, which are bent relative to the rigid PCB 17 of the ring-shaped body. The second embodiment of a PCB assembly 10a illustrates a combination of rigid PCB 17 and flexible PCB 14, allowing surface mount Hall-effect sensors 12 to be mounted while the PCB in a flat state as shown in FIG. 8. The completed PCB assembly 10a is then secured to a positioning ring 22 with the segments of flexible PCB 14 bent approximately 90° relative to the rigid PCB 17 as shown in FIG. 9. The positioning ring 22 and mounted PCB assembly 10a are ready for installation in a BLDC motor as discussed above.

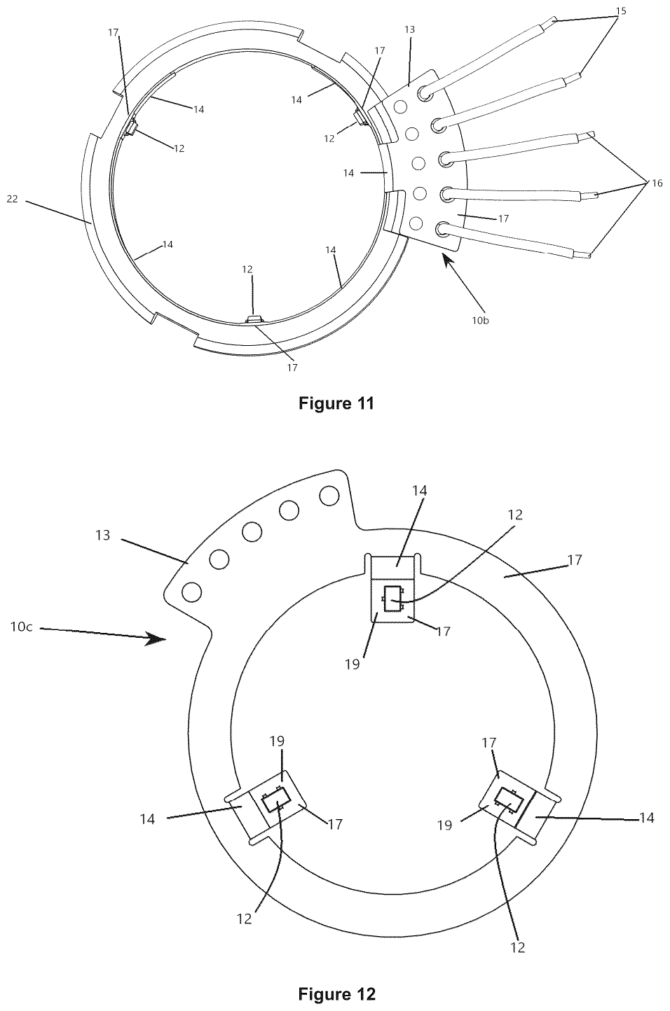

FIGS. 10 and 11 illustrate a third embodiment of a PCB assembly 10b according to aspects of the disclosure. FIG. 10 illustrates the PCB assembly 10b in a flat state after population with surface mount Hall-effect sensors 12, connection wires 15 and signal wires 16. The component locations 19 position the Hall-effect sensors 12 at equal distance D from each other. In this embodiment, the interconnect portion 13 and component locations 19 are constructed of rigid PCB 17, while the remainder of the PCB is flexible PCB 14. The PCB assembly 10b is completed in a flat state and then secured to a positioning ring 22 as shown in FIG. 11. The segments of flexible PCB 14 allow the elongated strip 18 to conform to the inside circumference of the positioning ring 22 and the interconnect portion to be bent radially outward across the top of the positioning ring 22. The PCB assembly may be secured to the positioning ring using adhesive, double sided tape or other methods known in the art. The positioning ring 22 and mounted PCB assembly 10b shown in FIG. 11 is ready for installation in a BLDC motor as discussed above.

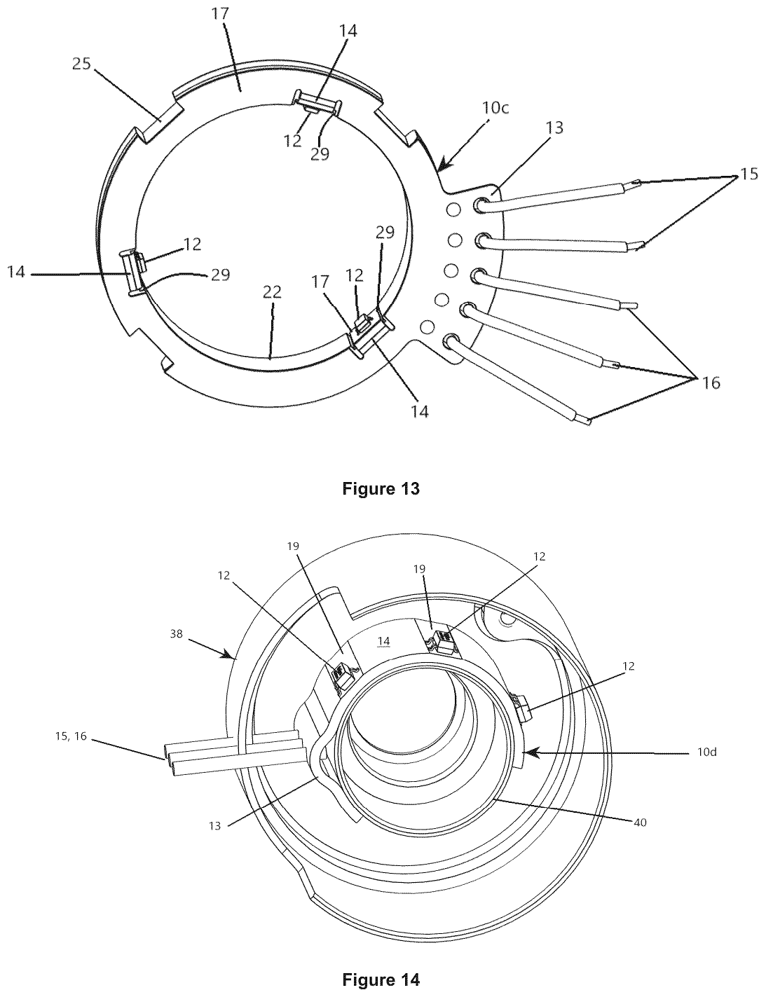

FIGS. 12 and 13 illustrate a fourth embodiment of a PCB assembly 10c according to aspects of the disclosure. The PCB assembly 10c is similar to PCB assembly 10a except that the component locations 19 are constructed of rigid PCB 17 and connected to the ring-shaped body by segments of flexible PCB 14. The segments of flexible PCB 14 allow the component locations 19 and Hall-effect sensors 12 to be bent 90° relative to the ring-shaped body of rigid PCB 17. The pockets 29 on the inside circumference of the positioning ring 22 are configured to receive the component locations 19 constructed of rigid PCB 17, which may be thicker than flexible PCB 14. The positioning ring 22 and mounted PCB assembly 10c shown in FIG. 13 is ready for installation in a BLDC motor as discussed above.

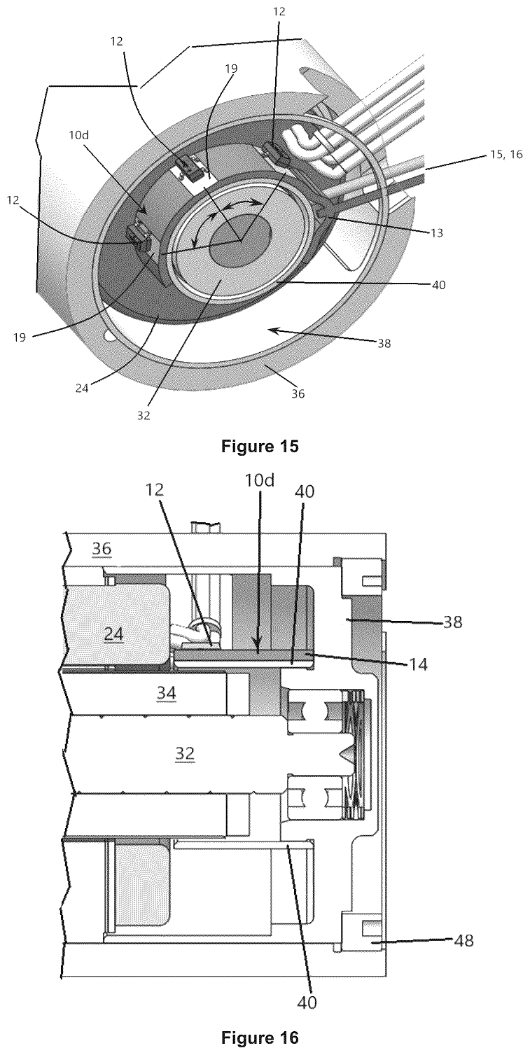

FIGS. 14-16 illustrate a fifth alternative implementation of the flexible PCB assembly 10d according to aspects of the disclosure. PCB assembly 10d includes a PCB constructed of flexible PCB 14, allowing the PCB to be populated with Hall-effect sensors 22 in a flat state and then secured to an outside circumference of a cylindrical surface in a BLDC motor. In this PCB assembly 10d, the Hall-effect sensors 12 are positioned at equal angles relative to each other, where the angles are less than 120°. FIG. 14 illustrates a motor end cap 38 for a BLDC motor that includes a cylindrical surface 40 to which the PCB assembly 10d is secured. The end cap 38 is then used to close one end of a BLDC motor, positioning the three, surface mount Hall-effect sensors 12 in a position axially overlapping with an end of the rotor 32 as shown in FIGS. 15 and 16. In this implementation, the connection wires 15 and signal wires 16 extend from the flexible PCB 14 radially away from the rotor 32 and are directed through a side of the end cap 38 along with the conductors for the stator coils to a motor control circuit such as illustrated in FIG. 1. The end cap 38 can be ferrous or other metal, with the cylindrical structure 40 preferably constructed of non-conductive material such as plastic to avoid interference with the magnetic field of the rotor magnets 34.

FIGS. 15 and 16 illustrate the PCB assembly 10d and motor end cap 38 secured to one end of a BLDC motor housing 36. Connection wires 15 and signal wires 16 from the PCB assembly 10d can be routed out of the motor housing 36 along the same path as conductors for the stator coils. In this implementation, the PCB assembly 10d can be secured to the cylindrical structure 40, which is then secured to the motor end cap that supports one of the motor shaft bearings. The motor end cap 38, cylindrical structure 40 and flexible PC board 12 can be rotated to adjust the position of the Hall-effect sensors 12 relative to the stator 24 and secured in the selected rotational position by a threaded ring 48 or other means of securing the end cap 38. In this implementation, the Hall-effect sensors 12 are on the radially outside surface of the flexible PCB 14 and radially spaced from the rotor 32.

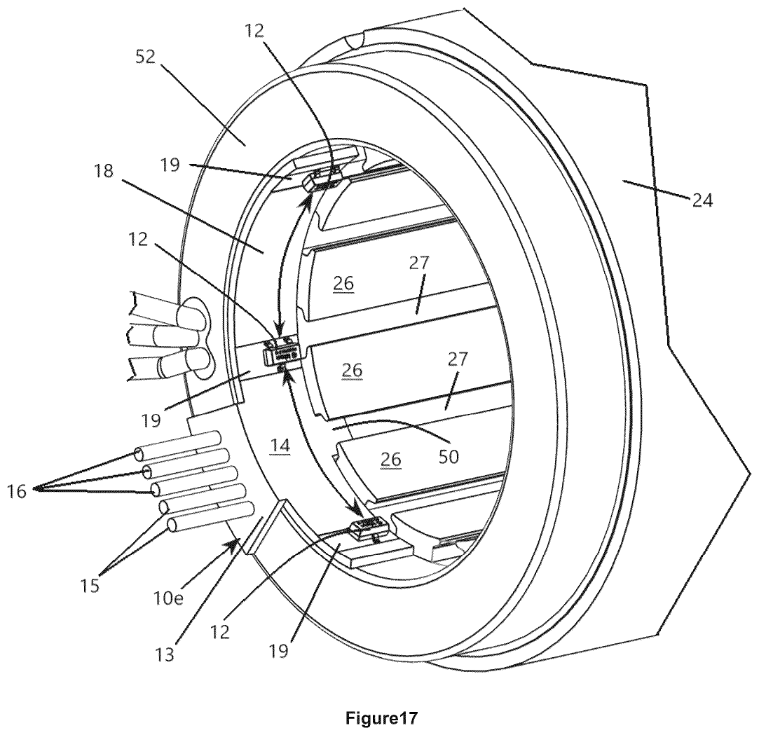

FIG. 17 illustrates a sixth implementation of a flexible PC board assembly 10e including a tab 50 projecting from the strip 18 of flexible PCB 14 to “clock” or index the Hall-effect sensors 12 relative to the stator 24. In this embodiment, the tab 50 is configured to be received between two poles 26 of the stator core 24. This configuration takes advantage of structures already present in the stator core 24, but it is possible to arrange a receptacle or pocket in another position inside the BLDC motor to receive a projection extending from a PCB assembly to establish a fixed position of the Hall-effect sensors 12 relative to the stator 24. This disclosed embodiment of a BLDC motor eliminates the positioning ring 22 shown in connection with PCB assemblies 10, 10a, 10b, and 10c. The end turn 52 of the stator 24 is configured with an inside circumference with a consistent cylindrical shape, allowing the PCB assembly 10e to be supported directly on the end turn 52. This configuration may be used to eliminate or minimize the need to adjust the position of the flexible PC board 12 relative to the stator 24 before securing the flexible PC board in place. The PCB assembly 10e positions the Hall-effect sensors 12 at equal angular positions relative to each other, where the angle between the Hall-effect sensors is less than 120°. In all other respects, the PCB assembly 10e of FIG. 17 is the same as that shown and described in FIG. 3.

What is claimed:

1. A BLDC motor comprising:
a stator having a plurality of windings;
a rotor supported for rotation relative to the stator, said rotor comprising a plurality of magnets of alternating polarity arranged on the rotor;
a printed circuit board (PCB) assembly comprising:
a printed circuit board (PCB) at least partially constructed of flexible PCB and defining a plurality of component locations and conductors extending from the component locations to an interconnect portion of the PCB assembly; and
a surface mount Hall-effect sensor secured to the PCB at each of the component locations, with electrical leads of the surface mount Hall-effect sensors connected to the conductors,
wherein the PCB is secured in a fixed position relative to the stator and the rotor, with the Hall-effect sensors positioned perpendicular to the magnetic flux of the magnets so that the Hall-effect sensors change state as each of the magnets passes each of the Hall-effect sensors, said flexible PCB allowing the PCB assembly to transition from a flat configuration to a configuration where the component locations are not in a common plane.

2. The BLDC motor of claim 1, wherein the PCB assembly comprises flexible PCB segments connecting the component locations to the PCB assembly.

3. The BLDC motor of claim 2, wherein the component locations comprise rigid PCB.

4. The BLDC motor of claim 2, wherein the interconnect portion comprise rigid PCB.

5. The BLDC motor of claim 1, wherein the entire PCB is constructed of flexible PCB.

6. The BLDC motor of claim 1, wherein a first end of the rotor extends axially outward from one end of the stator and the Hall-effect sensors are positioned about a circumference radially outward of the first end of the rotor.

7. The BLDC motor of claim 1, wherein the flexible PC board includes three equally spaced component locations and the component locations are positioned about a circumference radially outward of an end of the rotor.

8. The BLDC motor of claim 1 wherein the PCB includes a projection fitting between two poles of a stator core.

9. The BLDC motor of claim 1, wherein the PCB includes a projection received in an indexing pocket to define the fixed position of the PC board relative to the stator.

10. A method of supporting Hall-effect sensors in a BLDC motor, said BLDC motor comprising a stator having a plurality of windings, and a rotor supported for rotation relative to the stator, said rotor comprising a plurality of magnets of alternating polarity arranged on the rotor, said method comprising:
providing a printed circuit board (PCB) assembly comprising:
a printed circuit board (PCB) at least partially constructed of flexible PCB and defining a plurality of component locations and conductors extending from the component locations to an interconnect portion of the PCB assembly; and
mounting a surface mount Hall-effect sensor at each of the component locations while the component locations are in a common plane with electrical leads of the surface mount Hall-effect sensors connected to the conductors,
securing said PCB assembly to the stator with the Hall-effect sensors positioned to change state as each of the magnets pass each of the Hall-effect sensors, wherein the component locations are not in a common plane.
